(19) United States
(12) Patent Application Publication
(10) Pub. No.: US 2026/0169073 A1
(43) Pub. Date: Jun. 18, 2026

(54) MOTOR MONITORING DEVICE

(71) Applicant: FANUC CORPORATION, Yamanashi (JP)

(72) Inventors: Kenji SHIMIZU, Yamanashi (JP); Makoto HAGA, Yamanashi (JP)

(73) Assignee: FANUC CORPORATION, Yamanashi (JP)

(21) Appl. No.: 18/845,635

(22) PCT Filed: Jun. 14, 2022
(86) PCT No.: PCT/JP2022/023759

§ 371 Date: Sep. 10, 2024

(51) Int. Cl. G01R 31/34

(52) U.S. Cl. CPC G01R 31/343

(57) ABSTRACT

A motor monitoring device according to an aspect of the present disclosure which allows the state of a motor to be easily ascertained comprises: a rotational speed acquisition unit that acquires the rotational speed of the motor that operates according to an operation program; an output value acquisition unit that acquires the output value of the motor; a state information acquisition unit that acquires state information indicating the state of the motor which is different from the rotational speed and the output value; a history information storage unit that associates the rotational speed, the output value, and the state information acquired at predetermined timing and stores the result as history information with an identifier added; and a graph display unit that displays a graph in which a marker indicating a combination of the rotational speed and the output value is plotted with a label indicating the identifier in a graph area with one axis indicating the rotational speed and the other axis indicating the output value.

### TECHNICAL FIELD

The present invention relates to a motor monitoring device.

### BACKGROUND ART

For example, in motors such as spindle motors used in machine tools, where the load can significantly vary, there is a risk of overheating if a high load state persists and heat accumulates. Various time ratings can be set for such motors to ensure operation without overheating under specific conditions. For example, the time ratings specified in JIS-C4034-1 include continuous ratings enabling continuous operation, short-time ratings enabling operation for a certain period (load time) in a case where the operation starts at room temperature, and repetitive ratings enabling operation for a certain period (load time ratio) within a specified cycle time.

It has been proposed to estimate the time until a motor overheats while maintaining the current operational state (see, for example, Patent Document 1). Knowing the time until overheating can help determine whether the current machining operation can be completed.

### CITATION LIST

### Patent Document

Patent Document 1: Japanese Patent No. 5628994

### DISCLOSURE OF THE INVENTION

### Problems to be Solved by the Invention

However, estimating only the time until overheating does not allow for easily understanding the motor's operational safety and margin. Specifically, when the settings such as motor speed is adjusted to maximize the efficient machining while minimizing the margin for overheating, it is not easy to determine how much the set values should be increased or decreased. Therefore, a technique that allows for easily understanding the motor's state is desired.

### Means for Solving the Problems

The motor monitoring device according to one aspect of the present disclosure includes: a rotation number acquisition unit that acquires a rotation number of a motor operating in accordance with an operational program; an output value acquisition unit that acquires an output value of the motor; a state information acquisition unit that acquires state information indicating a state of the motor different from the rotation number and the output value; a history information storage unit that associates the rotation number, the output value, and the state information acquired at a predetermined timing, and stores this associated data as history information with an added identifier; and a graph display unit that displays a graph plotting a marker indicating a combination of the rotation number and the output value on a graph area, with one axis representing the rotation number and the other axis representing the output value, along with a label indicating the identifier.

### Effects of the Invention

According to the present disclosure, the motor's state can be easily understood.

### BRIEF DESCRIPTION OF THE DRAWINGS

FIG. 1 is a block diagram illustrating the configuration of a machine tool including a motor monitoring device according to the first embodiment of the present disclosure; and

FIG. 2 is a diagram illustrating a screen displayed by the motor monitoring device of FIG. 1.

### PREFERRED MODE FOR CARRYING OUT THE INVENTION

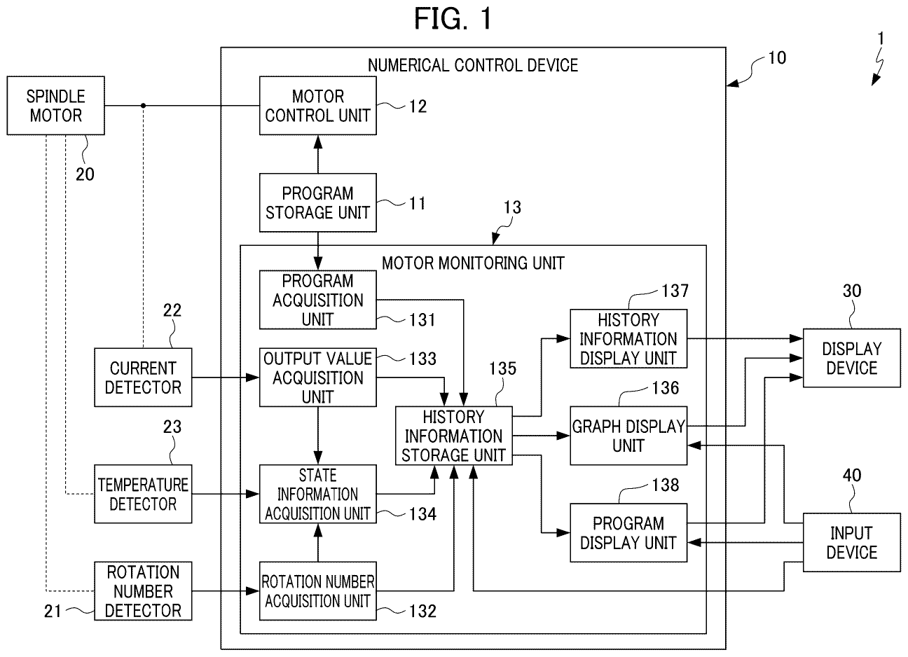

Hereinafter, embodiments of the present disclosure will be described with reference to the drawings. FIG. 1 is a block diagram illustrating the configuration of a machine tool 1 including a motor monitoring device according to the first embodiment of the present disclosure.

The machine tool 1 includes a numerical control device 10 as an embodiment of the motor monitoring device according to the present invention, a spindle motor 20, a rotation number detector 21 that detects the rotation number of the spindle motor 20, a current detector 22 that detects the current of the spindle motor 20, a temperature detector 23 that detects the winding temperature of the spindle motor 20, a display device 30 that displays a screen in accordance with the numerical control device 10, and an input device 40 used by the user to input into the numerical control device 10.

The numerical control device 10 controls the operation of the spindle motor 20 and other components in accordance with an operational program (referred to as a machining program in numerical control devices) to enable the machine tool 1 to perform predetermined machining on the workpiece. The numerical control device 10 includes a memory, a processor (CPU), input/output interfaces, etc., and can be implemented by one or more computer devices executing appropriate control programs. Components of the numerical control device 10 described below are categorized based on the functions of the numerical control device 10 and need not be distinctly separable in physical configuration and program configuration.

The spindle motor 20 is typically a motor that rotationally drives a cutting tool or workpiece. The spindle motor 20 operates in accordance with the operational program as described above, but the load can fluctuate independently of the rotation number, depending on the machining conditions. The rotation number detector 21, the current detector 22, and the temperature detector 23 can be composed of known sensors.

The display device 30 is a well-known display that displays in accordance with signals input from the numerical control device 10. The display device 30 may be integrated with the numerical control device 10. The input device 40 is a device used by the user to input information into the numerical control device 10 and may be composed of well-known components such as a keyboard or mouse. The input device 40 may also be integrated with the numerical control device 10. The input device 40 may also be integrated with the display device 30. Specifically, the display device 30 and the input device 40 may be a single input/output device such as a touch panel.

In the present embodiment, the numerical control device 10 includes: a program storage unit 11; a motor control unit 12 that controls the operation of motors that drive the drive axes of the machine tool 1 including the spindle motor 20; and a motor monitoring unit 13 that executes the functions of the motor monitoring device according to the present disclosure.

The program storage unit 11 stores operational programs executed by the machine tool 1. Each operational program includes a plurality of blocks that specify the unit operations of the machine tool 1. Each block includes one or more words formed by combinations of a plurality of characters (letters). Typically, each block is prefixed with a sequence number to identify the block.

The motor control unit 12 executes the machining procedures described in the operational program by controlling the spindle motor 20 and the motors of other drive axes of the machine tool 1 in accordance with the operational program. The configuration of the motor control unit 12 is the same as that of well-known numerical control devices, thus a detailed description is omitted.

The motor monitoring unit 13 includes a program acquisition unit 131, a rotation number acquisition unit 132, an output value acquisition unit 133, a state information acquisition unit 134, a history information storage unit 135, a graph display unit 136, a history information display unit 137, and a program display unit 138.

The program acquisition unit 131 acquires an operational program from the program storage unit 11 that specifies the operation to be monitored for the spindle motor 20. In other words, the program acquisition unit 131 loads the target operational program into the working memory.

The rotation number acquisition unit 132 acquires the rotation number of the spindle motor 20 from the rotation number detector 21. The rotation number acquisition unit 132 may also acquire the rotation number of the spindle motor 20 via the motor control unit 12.

The output value acquisition unit 133 acquires the output values of the spindle motor 20, such as a current value, a power value, and a torque value. In the present embodiment, the output value acquisition unit 133 is configured to acquire the current value of the spindle motor 20 from the current detector 22 and to use the power value calculated from the current value as the output value. However, the output value acquisition unit 133 may be configured to use the detected value such as the current value directly as the output value. The output value acquisition unit 133 may also acquire the output value or the values necessary to calculate the output value from the motor control unit 12. The output value acquisition unit 133 may acquire two or more types of output values.

The state information acquisition unit 134 acquires state information indicating the state of the spindle motor 20, different from the rotation number or the output value. In the present embodiment, the state information acquisition unit 134 calculates the estimated time to reach the overheating temperature in a case where the rotation number and the output value at that time are maintained by the spindle motor 20, based on the winding temperature of the spindle motor 20 acquired from the temperature detector 23 and the current value or output value acquired by the output value acquisition unit 133. This estimated time is one of the pieces of state information. The state information acquisition unit 134 may also use other indicators indicating the state of the spindle motor 20 as alternative or additional state information, such as using the winding temperature of the spindle motor 20 directly as state information. Furthermore, the state information may include program position information that identifies a position within the operational program, and modal information that specifies an operation of the spindle motor 20. The program position information may include sequence numbers, line numbers, and block numbers. Modal information may include commands extracted from the operational program (not limited to commands directly specifying an operation of the spindle motor 20, but also including commands that may affect an operation of the spindle motor 20, such as a command specifying a tool), and setting values of the numerical control device 10.

The history information storage unit 135 associates the rotation number, output value, and state information acquired at a predetermined timing, and stores them as history information with an added identifier. In other words, the history information storage unit 135 forms one record with the rotation number, output value, and state information of the spindle motor 20 at the same timing, and stores each record with an added unique identifier. The identifier can be a serial number or a timestamp.

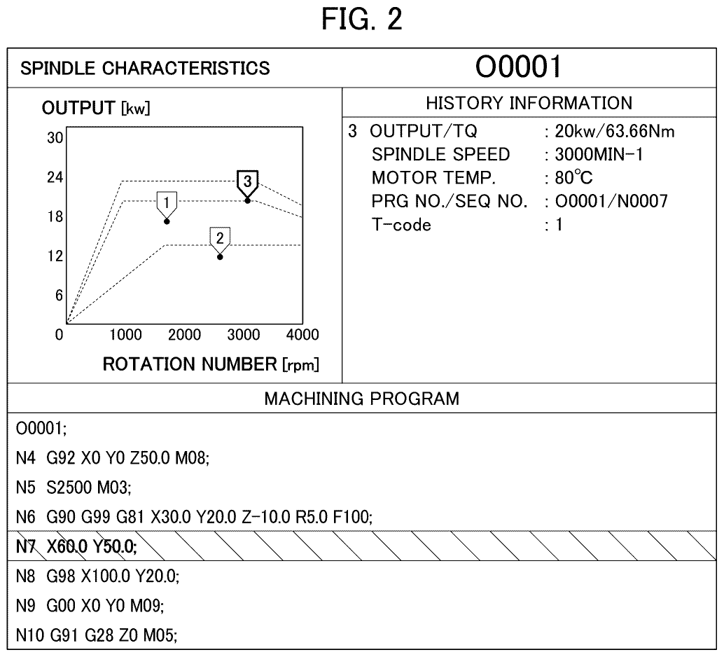

The timing for acquiring the rotation number, output value, and state information to be stored as history information by the history information storage unit 135 may include user-instructed timings, or when the combination of rotation number and output value reaches a predetermined load level, as well as when an abnormality is detected. The history information is stored at user-instructed timings, thereby allowing the user to check the state of the spindle motor 20 in detail at user's points of interest. The history information is stored when the combination of rotation number and output value reaches a predetermined load level, as well as when the numerical control device 10 detects an abnormality, thereby allowing for storing the information that the user should preferably check. When the graph area representing possible combinations of rotation number and output value is divided into a plurality of zones, the load level for storing the history information can be a zone with the maximum load level allowing for operation, such as a zone between a specific time rating and an instantaneous rating inclusive. In FIG. 2, the graph area is divided into four zones: a load zone allowing for continuous operation, a load zone allowing for intermittent operation, a load zone allowing for exceptional short-time operation, and a non-operational zone where even short-time operation is not allowed, based on the continuous rating, time rating, and maximum output indicated with dashed lines.

Furthermore, the history information storage unit 135 preferably confirms the rotation number, output value, and state information at regular time intervals, and stores a plurality of combinations of (a certain number of) rotation number, output value, and state information within a preset time range which is preset based on the predetermined timing (e.g., at the time closest to the specified timing and the time immediately therebefore) as one or individual pieces of history information. In this manner, a certain number of continuous information is stored at regular intervals, thereby allowing the user to confirm the rate of change in the operational state and understand the state of the spindle motor 20 more appropriately.

The graph display unit 136 displays a graph in the graph area, plotting markers that indicate the combination of rotation number and output value stored by the history information storage unit 135, with one axis representing the rotation number and the other axis representing the output value, along with a label indicating the identifier. In the example illustrated in FIG. 2, the label indicating the identifier is adjacent to the marker, but the label may be displayed on the marker by enlarging the marker or separated from the marker using a leader line. Displaying such a graph allows for visualizing the load on the spindle motor 20 and allows the user to easily identify the corresponding history information, i.e., information other than the rotation number and output value.

The graph display unit 136 preferably displays a graph in a manner that allows the user to select the markers to be displayed. The markers may be indirectly selected by selecting the labels. In FIG. 2, the marker labeled with the identifier “3” is selected via the graph display unit 136, and accordingly, the display details of the history information display unit 137 and the program display unit 138 are determined. The display details of the history information display unit 137 and the program display unit 138 can be selected with the markers displayed by the graph display unit 136, thereby allowing for easily identifying the history information and the portions of the operational program which need to be checked. Conversely, the graph display unit 136 may display markers corresponding to the history information that is distinctly displayed by the history information display unit 137.

The history information display unit 137 displays at least part of the history information corresponding to the marker selected by the user via the graph display unit 136. In FIG. 2, the details of the history information labeled with the identifier “3” are displayed on the history information display unit 137. The history information display unit 137 may include buttons for forward and backward scrolling the history information to allow for selecting the history information. In this manner, the display of the history information display unit 137 is aligned with the graph display unit 136, thereby allowing for improving operability.

The program display unit 138 displays at least part of the operational program. The program display unit 138 preferably provides a user interface that allows the user to edit the displayed operational program. In other words, the editing details of the operational program confirmed by the program display unit 138 can be reflected in the storage details of the program storage unit 11. The program display unit 138 preferably distinctly displays the portion identified by the program position information of the history information corresponding to the marker selected by the user via the graph display unit 136. In FIG. 2, the sequence number “N0007” of the program number “00001” identified by the history information of the marker with the identifier “3” selected via the graph display unit 136, and also the sequence numbers before and after “N0007”, are displayed. The portion corresponding to the selected marker with the identifier “3” is distinctly displayed. In this manner, the display of the program display unit 138 is aligned with the graph display unit 136, thereby allowing for improving operability.

The numerical control device 10 according to the present embodiment includes: the history information storage unit 135 that associates the rotation number, output value, and state information acquired at predetermined timings, and stores them as history information with an added identifier; and the graph display unit 136 that displays a graph plotting markers indicating the combination of rotation number and output value on a graph area, with one axis representing the rotation number and the other axis representing the output value, along with a label indicating the identifier. Therefore, the state of the spindle motor 20, including state information other than the rotation number and output value, can be easily understood.

Although the embodiments of the present disclosure have been described above, the present invention is not limited to the embodiments described above. The effects described in the above embodiments are merely examples of the preferred effects resulting from the present invention, and the effects of the present invention are not limited to those described in the above embodiments.

The motor monitoring device according to the present disclosure may be provided independently of the numerical control device that controls the machine tool, and may be used for monitoring the motors other than the spindle motor of the machine tool, such as the motor of a kneading machine. For example, the motor monitoring device according to the present disclosure may add the functions of the motor monitoring unit described in the above embodiments to a management computer that manages one or more numerical control devices, such as a control device for a kneading machine or a management computer that manages such a control device.

In the motor monitoring device according to the present disclosure, the history information display unit and the program display unit are optional configurations, and the graph display unit does not necessarily have to allow the selection of display positions by markers.

### EXPLANATION OF REFERENCE NUMERALS

1: machine tool
10: numerical control device (motor monitoring device)
11: program storage unit
12: motor control unit
13: motor monitoring unit
131: program acquisition unit
132: rotation number acquisition unit
133: output value acquisition unit
134: state information acquisition unit
135: history information storage unit
136: graph display unit
137: history information display unit
138: program display unit
20: spindle motor
21: rotation number detector
22: current detector
23: temperature detector
30: display device
40: input device

1. A motor monitoring device, comprising:
a rotation number acquisition unit that acquires a rotation number of a motor operating in accordance with an operational program;
an output value acquisition unit that acquires an output value of the motor;
a state information acquisition unit that acquires state information indicating a state of the motor, different from the rotation number and the output value;
a history information storage unit that associates the rotation number, the output value, and the state information acquired at a predetermined timing, and stores this associated data as history information with an added identifier; and
a graph display unit that displays a graph plotting a marker indicating a combination of the rotation number and the output value on a graph area, with one axis representing the rotation number and the other axis representing the output value, along with a label indicating the identifier.

2. The motor monitoring device according to claim 1, wherein the identifier is a timestamp or a serial number.

3. The motor monitoring device according to claim 1, wherein the predetermined timing includes when the combination of the rotation number and the output value reaches a predetermined load level, and when an abnormality is detected.

4. The motor monitoring device according to claim 1, wherein the predetermined timing includes a user-instructed timing.

5. The motor monitoring device according to claim 1, further comprising:
a history information display unit that displays at least part of the history information corresponding to the marker selected by a user via the graph display unit.

6. The motor monitoring device according to claim 1, further comprising:
a program display unit that displays at least part of the operational program, wherein
the state information includes program position information that identifies a position in the operational program, and
the program display unit displays a portion identified by the program position information of the history information corresponding to the marker selected by a user via the graph display unit.

7. The motor monitoring device according to claim 1, wherein the history information storage unit confirms the rotation number, the output value, and the state information at a regular time interval, and stores a plurality of combinations of the rotation number, the output value, and the state information within a preset time range based on the predetermined timing.

8. The motor monitoring device according to claim 1, wherein the state information includes modal information that specifies an operation of the motor.

9. The motor monitoring device according to claim 1, wherein the state information acquisition unit calculates, as one element of the state information, an estimated time to reach an overheating temperature in a case where the rotation number and the output value at that point in time are maintained by the motor.
